(19) United States
(12) Patent Application Publication
(10) Pub. No.: US 2013/0206738 A1
(43) Pub. Date: Aug. 15, 2013

(54) IN SITU INDUCTIVE ABLATION METER

(71) Applicant: FIRST SOLAR, INC., (US)

(72) Inventor: Charles E. Wickersham, Perrysburg, OH (US)

(73) Assignee: FIRST SOLAR, INC., Perrysburg, OH (US)

(21) Appl. No.: 13/761,797

(22) Filed: Feb. 7, 2013

Related U.S. Application Data
(60) Provisional application No. 61/597,456, filed on Feb. 10, 2012.

(51) Int. Cl. B23K 26/38; G01R 27/26

(52) U.S. Cl. CPC B23K 26/38; G01R 27/2611
USPC 219/121.68; 324/654

(57) ABSTRACT

Real time monitoring and detection of the depths of laser scribes used during pulsed laser ablation processes. During a laser scribing process, sensors are used to determine in real time an amount of ablated material from a substrate undergoing the process. Laser scribing can be terminated when the amount of ablated material as detected by the sensors corresponds to a desired scribe depth.

### CROSS-REFERENCE TO RELATED APPLICATION

This application claims priority to U.S. Provisional Application No. 61/597,456, filed Feb. 10, 2012, which is hereby fully incorporated by reference.

### TECHNICAL FIELD

This disclosure relates to measuring an amount of material removed by a laser during the manufacturing of a photovoltaic device.

### BACKGROUND

Photovoltaic devices such as photovoltaic modules (which are made of a plurality of photovoltaic cells) can include semiconductor and other materials deposited over a substrate using various deposition systems and techniques. One example is the deposition of a semiconductor material such as cadmium sulfide (CdS) or cadmium telluride (CdTe) thin films over a glass substrate. During manufacturing, these photovoltaic modules usually undergo several laser scribing processes to define the cells therein and to provide for electrical connections among the cells and to external devices.

As one can appreciate, photovoltaic cell definition is a highly complex process that is required to achieve maximal output power from each manufactured module. Laser scribing used for electrical isolation, connections, etc. is an essential aspect of this process. During the process, laser scribes must reach their proper depth to electrically isolate each cell and to allow subsequent metallization steps to properly form necessary electrical contacts/connections.

Presently, the process of determining whether depths of laser scribes are enough to provide for proper cell isolation involve: (1) selecting what is believed to be an appropriate operating laser power; (2) laser scribing the layers on the substrate to isolate the cells; and (3) inspecting the substrates after they have been processed to verify that proper cell isolation has been achieved. This process is necessary because of laser power fluctuations and non-uniformity of layer thicknesses. For example, power fluctuations during a laser scribing process may cause more or less material to be removed than desired. Variations in film thickness may lead to varying scribe depths among processed substrates. If the scribe depths are too shallow, then the scribing procedure must be repeated, which will cause a delay in the manufacturing process. If the scribe depths are too deep, the substrate may have to be recoated or scrapped, causing additional unwanted expense and delay. Accordingly, there is a need and desire for a better technique of controlling depths of laser scribes.

In addition, complete ablation of all layers around the edges of fully processed photovoltaic modules formed on glass substrates is required to ensure electrical isolation and to hermetically seal the modules. As such, processed photovoltaic modules undergo a procedure known as “laser edge delete” process. The laser edge delete process utilizes a laser to remove semiconductor materials and other films from a predefined area around the glass substrate. The substrate edges are then tested to ensure that the desired amount of material has been removed. A typical technique for testing the edges includes measuring the resistance of the substrate surface using probes. Unfortunately, this test may not always be accurate and may result in repeating the laser edge delete process until the desired edges are obtained. Accordingly, there is a need and desire for a technique for monitoring an amount of material removed by lasers during laser edge delete processes.

### DESCRIPTION OF DRAWINGS

FIG. 1 shows a system for manufacturing a photovoltaic device.

FIG. 2 shows a processing station comprising an apparatus for measuring an amount of material removed by a laser during the manufacturing of a photovoltaic device in accordance with an embodiment of the invention.

### DETAILED DESCRIPTION

The technology disclosed herein will provide real time monitoring and detection of the depths of laser scribes used during the photovoltaic module manufacturing process. During a laser scribing process, inductive sensors are used to determine in real time an amount of material ablated by the laser. Laser scribing is terminated, when the amount of ablated material as detected by the sensors corresponds to the desired scribe depth.

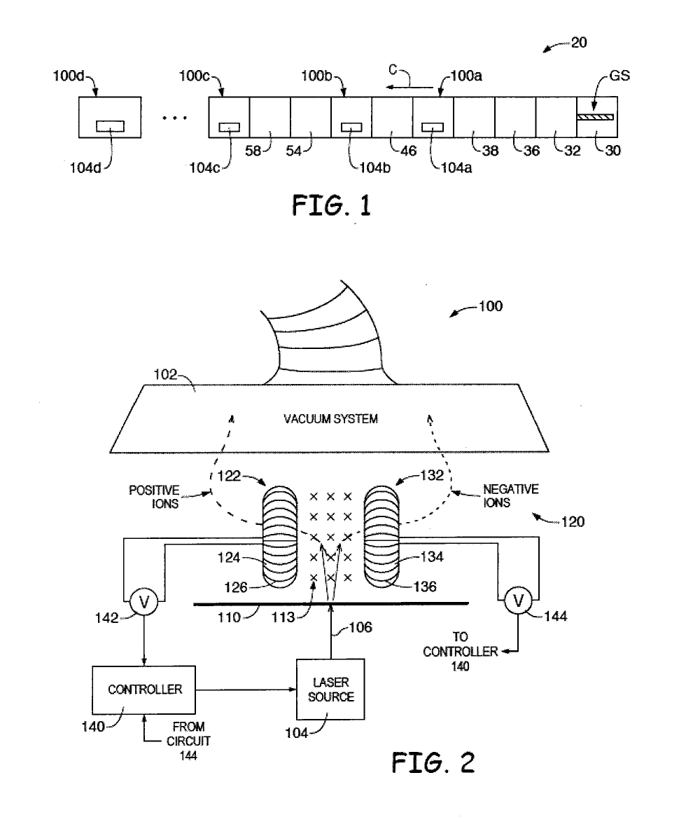

Referring to FIG. 1, one example of a system 20 suitable for manufacturing a photovoltaic module is now described. The system 20 can be e.g., the system disclosed in U.S. Pat. No. 6,559,411, assigned to First Solar, LLC. The system 20 includes several processing stations 30, 32, 36, 38, 46, 54, 58, 100a, 100b, 100c, each with its own function in the manufacturing process. In the illustrated system 20, stations 30, 32 and 54 are deposition/coating stations, stations 36, 38 and 58 are treating stations, stations 100a, 100b and 100c are laser scribing stations, and station 46 is a dielectric processing station. It should be appreciated that the number and types of stations in system 20 and the processing performed therein are mere examples and should not be construed to limit the embodiments of the invention disclosed herein.

A glass sheet substrate GS typically having one surface coated with a transparent conductive oxide (TCO), e.g., a tin oxide layer, is transported to a first deposition station 30 where a cadmium sulfide layer of about 3000 angstroms thick is deposited. The manufacturing proceeds as the glass sheet substrate is conveyed in the direction illustrated by arrow C to a second deposition station 32 where e.g., a cadmium telluride layer about 3 microns thick is deposited prior to moving through the first two treating stations 36, 38, which treat the deposited layers to ensure their adhesion to the substrate GS. The substrate is then conveyed to a first scribing station 100a, where a pulsed laser source 104a provides laser pulses for scribing a first set of scribes through the tin oxide, cadmium sulfide and the cadmium telluride layers. The scribes divide the conductive coating into strips. As will be explained below in more detail with reference to FIG. 2, scribing station 100a, as well as scribing stations 100b and 100c, comprises an in situ ablation monitoring apparatus 120 that measures, in real time, the amount of material removed by each laser pulse in the scribing process. By measuring the amount of removed material in real time, the apparatus 120 provides a way to ensure that the laser scribe depth is the desired depth in a more accurate and reliable manner than existing techniques.

After scribing the first set of scribes at the first scribing station 100a, the substrate is conveyed to the dielectric processing station 46 where the first set of scribes are filled with a dielectric material for isolation of the to-be formed cells. The substrate is conveyed to the second scribing station 100b where a second pulsed laser source 104b operating at a lower power level than the first laser source 104a provides laser pulses for scribing a second set of scribes through the cadmium sulfide and the cadmium telluride layers without scribing the tin oxide layer. The second set of scribes is used to interconnect the cells. As mentioned above, scribe depth in station 100b will be monitored in real time and assured of being the proper/desired depth by the novel apparatus 120 discussed below with reference to FIG. 2.

Upon leaving the second scribing station 100b, the substrate is conveyed to coating station 54 where an electrically conductive back contact layer is applied. The substrate is then moved to the third treatment station 58, which treats the coated layer to ensure its adhesion to the substrate GS. Once treated, the substrate is conveyed to the third scribing station 100c where a third laser source 104c operating at a lower power level than the second laser source 104b provides a third set of pulses for scribing through the back contact layer to provide segmented cells that are electrically connected to each other e.g., in series. Scribe depth in station 100c will be monitored in real time and assured of being the proper/desired depth by apparatus 120 (FIG. 2) contained within the station 100c.

The processed modules would also undergo the laser edge delete process in another downstream station 100d where a laser apparatus 104d removes semiconductor materials and other films from a predefined area (i.e., edge) around the glass substrate. Unlike conventional laser edge deletion processes, the amount of material removed is monitored in real time and assured of meeting safety and other requirements by the ablation monitoring apparatus 120 (FIG. 2) contained within the station.

FIG. 2 shows a processing station 100 comprising an ablation monitoring apparatus 120 for measuring an amount of material removed by a laser source 104 during the manufacturing of a photovoltaic device in accordance with an embodiment of the invention. In a desired embodiment, each laser scribing station 100a, 100b, 100c (FIG. 1) and part of the laser edge delete station would be configured as shown for station 100.

The illustrated monitoring apparatus 120 includes two inductive sensors 122, 132 and two measuring circuits 142, 144 that are connected to a controller 140 or other device (e.g., processor) used to control the laser source 104. In a desired embodiment, the first inductive sensor 122 consists of a toroid-shaped ferrite core 124 supporting a wire coil 126 connected to the first measuring circuit 142. Likewise, the second inductive sensor 132 consists of a toroid-shaped ferrite core 134 supporting a wire coil 136 connected to the second measuring circuit 144. It should be appreciated that the apparatus 120 could comprise one sensor and corresponding measuring circuit or it could comprise more than two sensors and measuring circuits, if desired.

During operation, the controller 140 enables the laser source 104 to direct laser pulses 106 at the substrate 110, causing material to be ablated and forming laser scribes in the substrate 110. At the same time, the ablated material is being sucked into a vacuum system 102. It should be noted that the ablated material being sucked in will generally have been ionized by the laser pulses. Ionization is a process by which atoms or molecules are converted into ions by adding or removing charged particles such as electrons or other ions. A positively charged ion is produced when an electron bonded to an atom (or molecule) absorbs a proper amount of energy to escape from its electric potential barrier that originally confined it, thus breaking the bond and freeing it to move. The amount of energy required is called the ionization energy. A negatively charged ion is produced when a free electron collides with an atom and is subsequently caught inside the electric potential barrier, releasing any excess energy. The laser pulses provide the ionization energy.

In any event, the passage of the ionized ablated material through the sensors 122, 132 generates a time-dependent magnetic field, which in turn induces an electromotive force in the sensor coils 126, 136, thereby generating a signal based on the amount of ionized material ablated from the substrate 110. The pulsed nature of the laser source causes the ablated material to be removed in discrete bursts as the energy is deposited in the material by each pulse. Any electromagnetic fields generated by the motion of these charged ions are therefore time-dependent. Moreover, any time-varying magnetic flux will induce an electric field with non-zero curl capable of driving current through an appropriate electrical circuit. An electromotive force is generated in the sensor coils by the passage of a quantity of ionized ablated material. This electromotive force will be measured by an external measurement circuit, such as a transimpedance amplifier (described below in more detail). The value measured will then be used to determine the amount of material removed with a suitable calibration curve or lookup table.

A static magnetic field 113 is established by a set of permanent or electromagnets (not shown). It is known that moving ions may be deflected by static magnetic fields according to the Lorentz force law. The direction of deflection will be opposite for ions of opposing charge. In this manner, the positive and negative ions in the ablation plume are steered to their respective sensor 122, 132, since one sensor 122 will attract one charge and the other sensor 132 will attract the opposite charge. Varying the strength of the static magnetic field, either by supplying a controllable current to the set of electromagnets, or by using permanent magnets of different strengths, would allow an operator to adjust the steering of the ablated ions.

The signals from each sensor 122, 132 are measured in the respective measuring circuit 142, 144 and summed at the controller 140. This summed signal will correspond directly to the amount of ablated material, which corresponds directly to the laser scribe depth and width. Since the scribe width is equal to the diameter of the beam of the laser, it will also be known. Thus, the depth of a scribe can easily be determined (described in more detail below). This will allow the controller 140 to determine when the laser scribes are at the correct depth and when to terminate the scribing process by, for example, disabling the laser source 104 for that station.

It should be appreciated that the film thicknesses are expected to vary within specified ranges as part of the normal manufacturing process. However, these thicknesses are easily measured (e.g., by a microspectrophotometer) and prerecorded to a database prior to the scribing and edge deletion processes. A plurality of measurements can be made along different portions of the substrate where the laser scribes are designed to go. The measurements can be used to interpolate/develop a “depth profile” which can be used by the controller to know how thick the films are in specified areas for each substrate to be processed. It may also be possible to use an average thickness as the thickness profile for the entire scribing process or a portion thereof. These thicknesses (e.g., the “depth profile”) are then used to determine what depth is required for each scribe or edge deletion and fed into the controller 140 as the stop criterion. It should also be appreciated that the desired scribe depth could be a depth within a predetermined range of scribe depths (taking into account the measured film thickness); as such, the controller 140 will be able to terminate the laser scribing process when it determines that the laser scribe's depth is within the desired range.

To determine the correlation between the signal produced by the sensors 122, 132 and the amount of ablated material, the controller 140 may include a table or set of hardware registers containing sensor signal values and their corresponding scribe depth. These values will be determined by a calibration routine, which can be done once per station 100 before any substrate processing is performed and/or during system down times when the station 100 is not being used to process photovoltaic modules. The first part of the calibration procedure will consist of scribing a test line on a coated substrate while measuring and summing the signals received from the sensors 122, 132. A laser scribe depth profile is then measured with device suitable for measuring scribe depth such as e.g., a Dektak profilometer or measured by atomic force microscopy (AFM). The measured depths are then correlated to the summed sensor signals. The correlated values are stored as part of a table, data structure, hardware registers, or other suitable device, which can then be used by the controller 140, e.g., as an index into the table, or selection of the appropriate register, to retrieve laser scribe depth based on the input summed sensor signal.

In a desired embodiment, the measurement circuits 142, 144 each utilize a transimpedance amplifier to convert the small current induced in the sensor's coil 126, 136, respectively, to a measureable voltage. The amplifier should have a high slew rate to keep up with the fast pulse frequency of the scribe lasers (e.g., 100-200 kHz).

As can be appreciated, an important parameter of the design of the sensors 122, 132 will be their response to transient signals. The sensors 122, 132 must be able to be excited by the passing ablated material, and then return to their unexcited state before the next laser pulse arrives. Thus, the relaxation time of the sensors 122, 132 must be less than the time between laser pulses. A large inductor of around 100 mH and a circuit resistance of approximately 100 k would ensure fast relaxation. Fine tuning of these values once the inductor is wound is also desirable to achieve critical damping.

When used for laser scribing, the disclosed apparatus 120 will provide in situ metrology of ablated material, which can facilitate an active feedback mechanism for controlling scribe depth via controller 140. The feedback mechanism, relying on inductive sensors 122, 132 and the correlation of scribe depth to sensor signals, will provide successful monitoring irrespective of fluctuations in laser power or variations in laser absorption by the material. Thus, the apparatus 120 is preferred because it is easier to detect the scribe depth in the disclosed “real time” manner than to have to measure electrical isolation in an offline process. Moreover, the disclosed scribe depth process allows each substrate to be checked, whereas the electrical isolation process is typically only performed on a small percentage of processed substrates. Currently, cell resistance of processed modules and sub-modules is expected to be measured on a daily basis, and thus only samples <0.05% of the manufacturing capacity. The techniques disclosed herein will enable 100% monitoring. Moreover, the disclosed apparatus 120 and technique will improve throughput of the overall manufacturing process and reduce waste by reducing the number of scrapped modules (because scribe depths will meet the necessary requirements).

The disclosed ablation monitoring apparatus 120 uses electromagnetic induction to detect ionized ablated material. Current methods utilize probes and/or electrodes that must touch the substrate and thus can become damaged or dirty requiring downtime to perform preventative maintenance of these probes/electrodes. In addition, the material on the probes may be hazardous and would require special care to maintain the safety of the maintenance personnel. The disclosed apparatus, on the other hand, will not incur any additional system down time because any gradual buildup of material on the sensors 122, 132 will have no effect on the performance of the sensors 122, 132 provided that the opening in the cores 124, 134 remains clear for the passage of the ions. Shields could be placed over the sensors 122, 132, which may then be removed and replaced by other shields in a manner of seconds, alleviating the need to scrub or clean the sensors 122, 132. The shields could be installed/replaced during periodic scheduled maintenance and would not add additional downtime for the system. Minimizing the amount of downtime for a station, or the system in general, is extremely desirable and achieved with the disclosed apparatus 120. Moreover, the apparatus 120 is beneficial from an environmental health and safety standpoint because it is compatible with existing vacuum systems used to collect hazardous materials such as cadmium.

It should be appreciated that the disclosed ablation monitoring apparatus 120 can also be used in a laser edge delete system or station. The laser edge deletion process would also use a “depth profile” of film thicknesses in the deletion region. The depth profile and the amount of ablated material will be used to verify that the edges of the modules are electrically isolated without having to do a resistance measurement. Thus, the laser edge delete process is simplified in addition to becoming more accurate using the disclosed apparatus 120.

Details of one or more embodiments are set forth in the accompanying drawings and description. Other features, objects, and advantages will be apparent from the description, drawings, and claims. Although a number of embodiments of the invention have been described, it will be understood that various modifications can be made without departing from the scope of the invention. Also, it should also be understood that the appended drawings are not necessarily to scale, presenting a somewhat simplified representation of various features and basic principles of the invention. The invention is not intended to be limited by any portion of the disclosure and is defined only by the appended claims.

What is claimed is:

1. A system comprising:
a laser adapted to output laser pulses to a substrate to remove material from the substrate; and
a monitoring apparatus adapted to sense a magnetic field corresponding to an amount of material removed from the substrate.

2. The system of claim 1, wherein the monitoring apparatus controls the laser to output the laser pulses until it determines that a predetermined amount of material has been removed from the substrate.

3. The system of claim 1, wherein the monitoring apparatus comprises:
at least one inductive sensor adapted to sense the material removed from the substrate; and
at least one measuring circuit, each at least one measuring circuit being connected to and associated with a respective one of said at least one inductive sensor, said at least one measuring circuit being adapted to output a measurement signal corresponding to the amount of material sensed by its associated sensor.

4. The system of claim 3, further comprising a controller connected to receive output measurement signals from the at least one measuring circuit and being adapted to determine a laser scribe depth from the received output measurement signals.

5. The system of claim 4, wherein the controller is adapted to control the laser to output the laser pulses until the controller determines that the laser scribe depth is at a predetermined desired scribe depth.

6. The system of claim 4, wherein the controller is adapted to control the laser to output the laser pulses until the controller determines that the laser scribe depth is within a predetermined range of desired scribe depths.

7. The system of claim 1, wherein the monitoring apparatus comprises:
first and second inductive sensor adapted to sense the material removed from the substrate; and
first and second measuring circuits, said first measuring circuit being connected to and associated with said first inductive sensor, said second measuring circuit being connected to and associated with said second inductive sensor, said first measuring circuit being adapted to output a first measurement signal corresponding to the amount of material sensed by said first inductive sensor, and said second measuring circuit being adapted to output a second measurement signal corresponding to the amount of material sensed by said second inductive sensor.

8. The system of claim 7, further comprising a controller connected to receive output first and second measurement signals from the first and second measuring circuits and being adapted to determine a laser scribe depth from the summation of the first and second measurement signals.

9. The system of claim 7, wherein the controller is adapted to control the laser to output the laser pulses until the controller determines that the laser scribe depth is at a predetermined desired scribe depth.

10. The system of claim 7, wherein the controller is adapted to control the laser to output the laser pulses until the controller determines that the laser scribe depth is within a predetermined range of desired scribe depths.

11. The system of claim 7, wherein the first inductive sensor senses positively charged ions within the removed material and the second inductive sensor senses negatively charged ions within the removed material.

12. The system of claim 1, wherein the monitoring is performed in real time.

13. A monitoring apparatus adapted to sense in real time an amount of material removed from a substrate by a laser, said apparatus comprising:
at least one inductive sensor adapted to sense the material removed from the substrate; and
at least one measuring circuit, each at least one measuring circuit being connected to and associated with a respective one of said at least one inductive sensor, said at least one measuring circuit being adapted to output a measurement signal corresponding to the amount of material sensed by its associated sensor.

14. The monitoring apparatus of claim 13, further comprising a controller connected to receive output measurement signals from the at least one measuring circuit and being adapted to determine a laser scribe depth from the received output measurement signals.

15. The monitoring apparatus of claim 14, wherein the controller is adapted to control a source of the laser to output laser pulses until the controller determines that the laser scribe depth is at a predetermined desired scribe depth.

16. The monitoring apparatus of claim 14, wherein the controller is adapted to control a source of the laser to output the laser pulses until the controller determines that the laser scribe depth is within a predetermined range of desired scribe depths.

17. A monitoring apparatus adapted to sense in real time a laser scribe depth in a substrate being processed by a laser, said apparatus comprising:
first and second inductive sensor adapted to sense material removed from the substrate;
first and second measuring circuits, said first measuring circuit being connected to and associated with said first inductive sensor, said second measuring circuit being connected to and associated with said second inductive sensor, said first measuring circuit being adapted to output a first measurement signal corresponding to an amount of material sensed by said first inductive sensor, and said second measuring circuit being adapted to output a second measurement signal corresponding to an amount of material sensed by said second inductive sensor; and
a controller connected to receive output first and second measurement signals from the first and second measuring circuits and being adapted to determine the laser scribe depth from the summation of the first and second measurement signals.

18. The monitoring apparatus of claim 17, wherein the controller is adapted to control a source of the laser to output laser pulses until the controller determines that the laser scribe depth is at a predetermined desired scribe depth.

19. The monitoring apparatus of claim 17, wherein the controller is adapted to control a source of the laser to output laser pulses until the controller determines that the laser scribe depth is within a predetermined range of desired scribe depths.

20. The monitoring apparatus of claim 17, wherein the first inductive sensor senses positively charged ions within the removed material and the second inductive sensor senses negatively charged ions within the removed material.

21. The monitoring apparatus of claim 17, wherein the controller comprises a table correlating measurement signals to scribe depth levels.

22. The monitoring apparatus of claim 17, wherein the controller comprises a data structure correlating measurement signals to scribe depth levels.

23. The monitoring apparatus of claim 17, wherein the controller comprises a set of hardware registers correlating measurement signals to scribe depth levels.

24. A method comprising:
sensing, using at least one inductive sensor, ablated material from a substrate being processed by a laser; and
determining a laser scribe depth from the sensed ablated material.

25. The method of claim 24, wherein the sensing and determining steps are performed in real time as the substrate is being processed by the laser.

26. The method of claim 24, wherein said sensing step comprises:
sensing positively charged ablated material using a first inductive sensor; and
sensing negatively charged ablated material using a second inductive sensor.

27. The method of claim 26, wherein said determining step comprises:
inputting a first signal corresponding to the sensed positively charged ablated material;
inputting a second signal corresponding to the sensed negatively charged ablated material;
summing the input first and second signals; and
indexing a table of laser scribe depths using the summed first and second signals.

28. The method of claim 26, wherein said determining step comprises:
inputting a first signal corresponding to the sensed positively charged ablated material;
inputting a second signal corresponding to the sensed negatively charged ablated material;
summing the input first and second signals; and
indexing a data structure comprising laser scribe depths using the summed first and second signals.

29. The method of claim 26, wherein said determining step comprises:
inputting a first signal corresponding to the sensed positively charged ablated material;
inputting a second signal corresponding to the sensed negatively charged ablated material;
summing the input first and second signals; and
accessing a hardware register from a set of hardware registers comprising laser scribe depths using the summed first and second signals.

30. The method of claim 24, further comprising the step of controlling a source of the laser to output laser pulses until it is determined that the laser scribe depth is at a predetermined desired scribe depth.

31. The method of claim 24, further comprising the step of controlling a source of the laser to output laser pulses until it is determined that the laser scribe depth is within a range of predetermined desired scribe depths.

32. The method of claim 24, further comprising the step of determining that an edge of the substrate has completed a laser edge deletion process.
